(19) United States
(12) Patent Application Publication
(10) Pub. No.: US 2025/0377595 A1
(43) Pub. Date: Dec. 11, 2025

(54) POLYMERS WITH PHOTOSELECTIVE POLYMERIZATION AND DEGRADATION PATHWAYS

(71) Applicant: Lawrence Livermore National Security, LLC, Livermore, CA (US)

(72) Inventors: Benjamin Martin Alameda, Livermore, CA (US); Magi Mettry Yassa, Antioch, CA (US); Martin Patrick De Beer, Berkeley, CA (US); Holden Johannes Howard, Livermore, CA (US); Dongping Terrel-Perez, Livermore, CA (US); Johanna Jesse Schwartz, Las Vegas, NV (US); Isabel Fabiola Arias Ponce, Pleasanton, CA (US); Ishan Dhiren Joshipura, Oakland, CA (US)

(21) Appl. No.: 19/203,045

(22) Filed: May 8, 2025

Related U.S. Application Data
(60) Provisional application No. 63/656,502, filed on Jun. 5, 2024.

(51) Int. Cl. G03F 7/039; C08G 75/00; C09D 181/00; G03F 7/20

(52) U.S. Cl. CPC G03F 7/0392; C08G 75/00; C09D 181/00; G03F 7/2002

(57) ABSTRACT

A photopolymer resin, in accordance with one embodiment, is capable of polymerization by exposure to polymerizing light, and characterized as enabling depolymerization of a resulting polymer product by exposure to depolymerizing light. A photopolymer resin, in accordance with another embodiment, includes one or more pH labile monomers that include one or more polymerizable functional handles, >0 to about 5 wt % of a polymerizing light-sensitive photoinitiator, and 0.01 to about 3 wt % of a depolymerizing light-responsive photoacid generator or photobase generator. A method, in accordance with one embodiment, includes exposing at least predefined portions of a photopolymer resin comprising one or more pH labile monomers and a photoinitiator to polymerizing light for causing polymerization of an exposed portion of the photopolymer resin thereby creating a polymer product, wherein the photopolymer resin further comprises a photoacid generator or photobase generator that is responsive to depolymerizing light.

### RELATED APPLICATIONS

This application claims priority to U.S. Provisional Patent Application No. 63/656,502, filed Jun. 5, 2024, which is herein incorporated by reference in its entirety.

This invention was made with Government support under Contract No. DE-AC52-07NA27344 awarded by the United States Department of Energy. The Government has certain rights in the invention.

### FIELD OF THE INVENTION

The present invention relates to photopolymers, and more particularly, this invention relates to photopolymerization resins capable of photopolymerization in one range of light wavelengths and depolymerization in another range of light wavelengths, and related products and methods.

### BACKGROUND

To the inventors' knowledge, no photopolymer system exists that uses a photoacid or photobase generator to provide spatially controlled and photo selective degradation, along with an orthogonal printing process.

### SUMMARY

A photopolymer resin, in accordance with one embodiment, is capable of polymerization by exposure to polymerizing light, and characterized as enabling depolymerization of a resulting polymer product by exposure to depolymerizing light.

A photopolymer resin, in accordance with another embodiment, includes one or more pH labile monomers that include one or more polymerizable functional handles, >0 to about 5 wt % of a polymerizing light-sensitive photoinitiator, and 0.01 to about 3 wt % of a depolymerizing light-responsive photoacid generator or photobase generator.

A method, in accordance with one embodiment, includes exposing at least predefined portions of a photopolymer resin comprising one or more pH labile monomers and a photoinitiator to polymerizing light for causing polymerization of an exposed portion of the photopolymer resin thereby creating a polymer product, wherein the photopolymer resin further comprises a photoacid generator or photobase generator that is responsive to depolymerizing light.

### BRIEF DESCRIPTION OF THE DRAWINGS

FIG. 1 is a depiction of an exemplary pH labile monomer and an exemplary additional monomer, in accordance with one embodiment.

FIG. 2 is a depiction of exemplary components of a photoinitiator, in accordance with one embodiment.

FIG. 3 is a depiction of an exemplary photoacid generator, in accordance with one embodiment.

FIG. 4 is a depiction of exemplary additive, in accordance with one embodiment.

FIG. 5 is a depiction of exemplary additive, in accordance with one embodiment.

FIG. 6 is a flowchart of a method, in accordance with one embodiment.

FIG. 7 is an image of a polymer layer formed from BMA L007 and PETMP, with triarylsulfornium hexafluoroantimonate therein as the photoacid generator, in accordance with one embodiment.

FIG. 8 is a chart demonstrating visible light gelation and subsequent degradation of an exemplary formulation, measured as modulus vs. time, in accordance with one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

As used herein, the term “about” denotes an interval of accuracy that promotes the technical effect of the feature in question. In various approaches, the term “about” when combined with a value, refers to ±10% of the reference value.

The following disclosure describes a photopolymer resin capable of (1) polymerization upon irradiation of polymerizing light having a wavelength in a first range and (2) the ability of a polymer product formed from the photopolymer resin to be depolymerized by irradiation with depolymerizing light having a wavelength in a second wavelength range that is different than the first range. The chemical photoselectivity of the polymerization and depolymerization reaction mechanisms enables the material to be polymerized and subsequently depolymerized on demand, and in some approaches, with spatial accuracy of polymerization and/or depolymerization. More detailed information is provided below.

Various aspects include a photopolymer resin capable of polymerization by exposure to polymerizing light, which is light having a wavelength (or wavelengths) in a first range that causes polymerization of one or more components in the resin to thereby form a polymer product, with the added capability of depolymerization of portions or all of the resulting polymer product by exposure to depolymerizing light, which is light having a wavelength (or wavelengths) in a second range that causes significant depolymerization of the polymer product. The photoselectivity of both processes allows for, inter alia, deliberate and spatially accurate control for adding and removing polymer material.

In one approach, a photopolymer resin formulation includes (1) one or more pH labile monomers that include one or more polymerizable functional handles such as one or more acrylates, one or more methacrylates, one or more alkenes, one or more thiols, and/or one or more epoxies; (2) a photoinitiator that is sensitive to polymerizing light, e.g., visible light; (3) a photoacid or photobase generator that is responsive to depolymerizing light, e.g., UV light; and optionally, and (4) one or more other additives such as a reactive diluent, an unreactive diluent, a pH stabilizer, etc. including multiples of a particular type of additive, and/or combinations of such additives.

A pH labile monomer is one that undergoes structural changes and/or degradation in response to changes in the pH of the surrounding environment. The pH labile monomer may be any suitable pH labile monomer that would become apparent to one skilled in the art after reading the present disclosure. In some approaches, the pH labile monomer(s) are of a type known in the art to form polymers that are pH labile, meaning the polymer disintegrates, at least to some extent, in the presence of acidic and/or basic conditions in its surrounding environment. U.S. Provisional Patent Application No. 63/656,502, which has been incorporated by reference, provide examples and fabrication paths for pH labile monomers that may be used in various approaches.

One general class of pH labile monomers includes those with a ketal group that is pH labile, and polymerizable functional handles (also referred to herein as crosslinkers), such as the aforementioned pH labile acrylates, methacrylates, alkenes, thiols, and/or epoxies. Other general classes of pH labile monomers include pH labile acetals, esters, borate esters, anhydrides, and imines. In one approach, this monomer occupies up to about 48% by weight of the formulation.

Examples of polymerizable functional handles (crosslinkers) include vinyl, acrylate, urea, or other crosslinkers that will create a polymer in the presence of an initiator upon activation. Other classes of pH labile monomers may be based on functional groups (other than ketal) that are known to be pH labile, along with the polymerizable functional handles. Two examples of pH labile monomers are dibenzo[c,e]-oxepane-5-thione (DOT) and 2-methylene-1,3-dioxepane (MDO), both of which cleave under basic conditions.

In some approaches, the pH labile monomer includes a dialkene ketal monomer.

In some approaches, the pH labile monomer includes a bisalkene diketal monomer configured to polymerize into a poly(β-thioether ester ketal) network that is degradable, and in some cases, completely degradable under acidic or basic conditions. In some approaches, the bisalkene diketal monomers may be bisalkene diketal monomers with a mercaptopropionate-based trifunctional thiol.

For example, degradable poly(β-thioether ester ketal) networks may be formed via thiol-ene photopolymerization using bis-allyl acyclic ketal monomers derived from acetone, cyclopentanone, or cyclohexanone. U.S. Provisional Patent Application No. 63/656,502, which has been incorporated by reference, provides fabrication paths for such polymers.

One or more additional monomers, that is/are different than the one or more pH labile monomers, may be present in the resin, to polymerize with the pH labile monomer. Examples include thiols such as ETTM P 1300 sold by Bruno Bock having a sales office at Glenpointe Center West 4 Floor 500 Frank W. Burr Boulevard, Teaneck, NJ 07666. See, e.g., U.S. Provisional Patent Application No. 63/656,502, which has been incorporated by reference, for more examples of additional monomers. Pentaerythritol tetrakis (3-mercaptopropionate) (PETMP) and trimethylolpropane diallyl ether are two additional examples of monomers that can be polymerized with pH labile monomers. Known additional monomers that would become apparent to one skilled in the art after reading the present disclosure may be used in various embodiments.

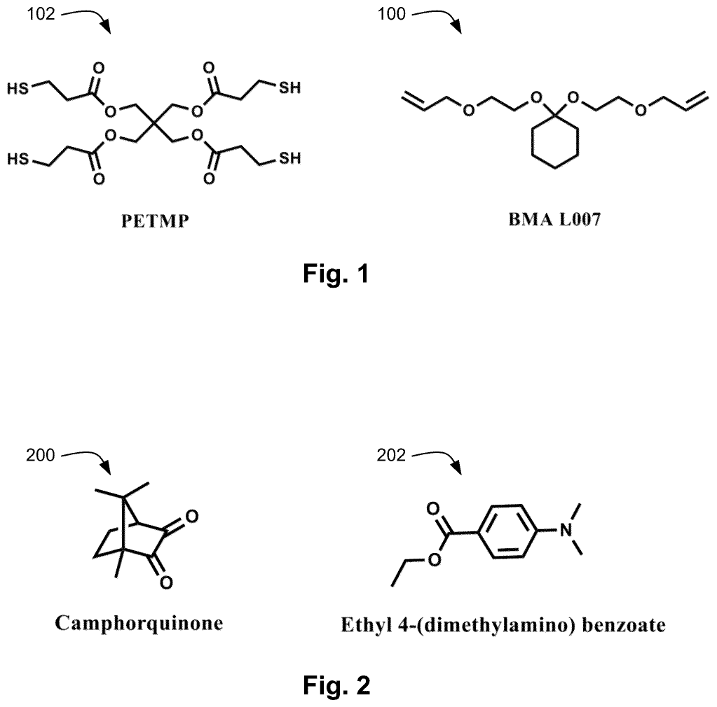

In one approach, shown in FIG. 1. a pH labile monomer is BMA L007 100 and the additional monomer is a thiol, namely PETMP 102. The SH group of the PETMP and the double bonded crosslinker of the BMA L007 form a thermoset that bonds during curing. The pH labile functional group of BMA L007 is the oxygen-cycle ketal portion, while the double bonded atoms at the ends are the crosslinkers.

The resin may also include a photoinitiator sensitive to polymerizing light. The photoinitiator may be any known photoinitiator based on the desired wavelength of polymerizing light, to cause polymerization of the resin upon exposure of the resin to polymerizing light. Likewise, the polymerizing light may be any light that includes a wavelength that causes the desired polymerization in the presence of the photoinitiator. In some approaches, the polymerizing light is visible light, light having a wavelength or wavelength range within the spectrum of visible light, UV light, etc.

In various approaches, the photoinitiator may be Darocur 1173 or the like. Darocur 1173 is available from Ciba. Other examples of visible light photoinitiators include Diphenyl (2,4,6-trimethylbenzoyl) phosphine oxide (TPO), available from Sigma-Aldrich; Phenylbis (2,4,6-trimethylbenzoyl) phosphine oxide (BAPO) (0.1-1%), available from Sigma-Aldrich; and Irgacure 784, available from Ciba.

In various approaches, the photoinitiator may be a photoinitiator created from camphorquinone 200 and ethyl 4-(dimethylamino) benzoate 202, shown in FIG. 2. The resulting photoinitiator is active at light at about 455 nm.

The resin also includes a photoacid or photobase generator that is responsive to depolymerizing light. The photoacid or photobase generator may be any known photoacid or photobase generator that is responsive to a particular wavelength of depolymerizing light to form an acid or a base upon exposure thereof to the depolymerizing light. Photoacid generators, as used herein, may include conventional photoacid generators (PAGs) and conventional photoacids (PAHs).

Whether a photoacid or photobase generator is used may depend on which pH labile monomer is used in the resin, so that the acid or base causes the desired degradation of the polymer. The photoacid or photobase generator may be present at 0.5-5% weight percent in the resin to achieve the desired effect, though the concentration thereof could be higher in some approaches. Any known photoacid or photobase generator that would become apparent to one skilled in the art after reading the present disclosure may be used.

In one approach, the photoinitiator is activated by visible light, preferably blue light in the visible spectrum, while the photoacid or photobase generator is activated by UV light. For example, when irradiated with UV light, the photoacid generator releases free acid in the polymer, which can react with the pH labile species and degrade the thermoset network. In another approach, the photoinitiator is activated by UV light, while the photoacid or photobase generator is activated by visible light.

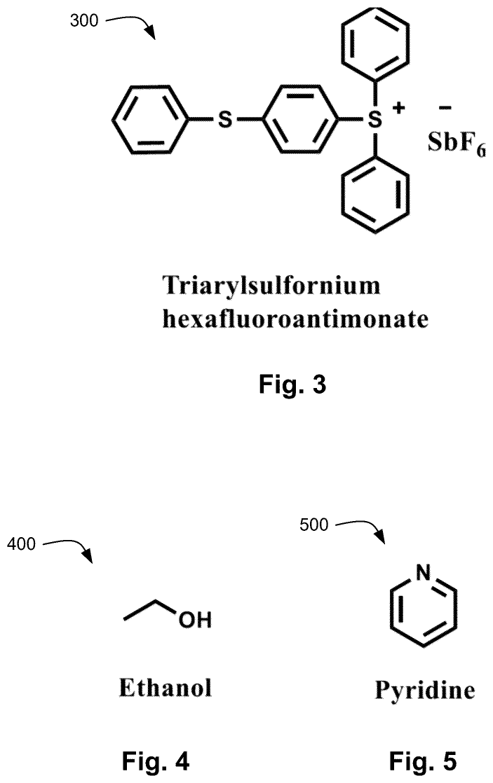

In one approach, depicted in FIG. 3, triarylsulfornium hexafluoroantimonate 300 may be used as a photoacid generator, which creates acid when exposed to UV light at 365 nm. This is typically used at 0.5-5% weight percent in the resin to achieve the desired effect. 4-[(2-hydroxytetradecyl)oxy]phenyl] phenyliodonium hexafluoroantimonate (HOPH) and diphenyliodonium hexafluorophosphate (DPI) are other examples of photoacid generators that may be used in the formulation.

The resin may include one or more other additives. Such additives may include any known additive capable of providing a desired function or property to the resin and/or polymer product. Examples include reactive diluents, unreactive diluents, pH stabilizers, etc. Each additive may be present in an effective amount to provide the desired function or property. A combination of additives may be present in the resin.

U.S. Provisional Patent Application No. 63/656,502, which has been incorporated by reference, provides examples of additives that may be used in various embodiments. Any additive that would become apparent to one skilled in the art after reading the present disclosure may be used in an effective amount. Further examples of additives follow.

In one approach, a distribution enhancing additive may be added to assist in the distribution of the acid from photoacid generator to the pH labile moieties. In one approach, shown in FIG. 4, ethanol 400 is used in the formulation for this purpose, at about 5-15 weight percent. Another similar chemical that may be used in place of ethanol is propylene glycol, which achieves the same function.

In another approach, a quencher (acid inhibitor) such as pyridine 500 may be added to function as so that the acid produced does not continue to degrade the polymer much beyond the portion desired to be disintegrated. See FIG. 5. Use of a quencher in turn enables selective degradation with higher spatial resolution. In one approach, pyridine is used in the formulation at about 0.05-0.5 weight percent. Another example of an alternative base is quinoline, another organic base.

The components (1)-(3), and optionally (4) of the resin should each be present in the resin in an effective amount to provide the desired characteristic, property and/or functionality. Illustrative amounts of the various components by wt % relative to the total weight of the resin are as follows: >0 to about 5 wt % photoinitiator, 0.01 to about 3 wt % photoacid generator or photobase generator, 0 to about 15 wt % additive(s), and the remainder monomer(s) (e.g., pH labile monomer(s) and any comonomer(s)). Some approaches may have higher concentrations than those shown here, Moreover, if the photoacid generator concentration in the polymer product is too low, the degradation may be partial, resulting in a partial depolymerization, e.g., the polymer product remains solid but is weakened.

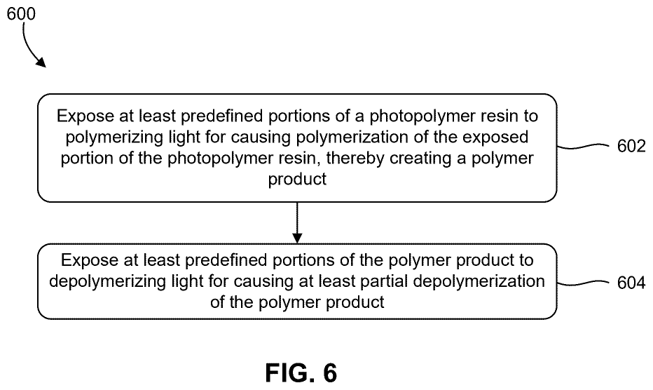

FIG. 6 graphically depicts a method 600 for forming a polymer product from a photopolymer resin, in accordance with one embodiment. As an option, the present method 600 may be implemented to construct structures, devices, etc. such as those shown in the other FIGS. described herein. Of course, however, this method 600 and others presented herein may be used to form structures for a wide variety of devices and/or purposes which may or may not be related to the illustrative embodiments listed herein. Further, the methods presented herein may be carried out in any desired environment. Moreover, more or less operations than those shown in FIG. 6 may be included in method 600, according to various embodiments. It should also be noted that any of the aforementioned features may be used in any of the embodiments described in accordance with the various methods.

In step 602, at least predefined portions of a photopolymer resin (according to any embodiment set forth herein) are exposed to polymerizing light, e.g., visible light, for causing polymerization of the exposed portion of the photopolymer resin, thereby creating a polymer product. The photopolymer resin includes at least a pH labile monomer, a photoinitiator that is sensitive to the polymerizing light, and a photoacid generator or photobase generator that is responsive to depolymerizing light.

In optional step 604, at least predefined portions of the polymer product are exposed to depolymerizing light, e.g., UV light, for causing at least partial depolymerization of the polymer product.

U.S. Provisional Patent Application No. 63/656,502, which has been incorporated by reference, provides examples and fabrication paths that may be adapted according to the teachings herein, e.g., by addition of an effective amount of a photoacid or photobase generator, for formation of photodegradable polymeric networks according to various approaches.

The photopolymer resin may be used to form 2D and/or 3D structures. For example, the photopolymer resin may be spread across a substrate to form a layer, and then exposed to polymerizing light to polymerize some or all of the layer. In another example, the photopolymer resin may be cast, molded, etc. prior to and/or during exposure to polymerize the resin. In yet another example, the photopolymer resin may be used to create a 3D structure via any additive manufacturing technique that is suitable for forming products from resins. Exemplary additive manufacturing techniques include vat polymerization processes such as stereolithography (SLA), digital light processing (DLP), and continuous liquid interface production (CLIP). In yet other approaches, other additive manufacturing techniques are used, such as microstereolithography (PμSL), direct ink writing (DIW), extrusion printing, and others. A side from selection of the wavelength of light according to the teachings herein, other aspects of the formation techniques may be conventional.

In one approach, the photopolymer resin is capable of polymerization upon irradiation of visible light (typically with wavelengths between 400 and 500 nm), and the ability to be depolymerized into liquid by-products under UV irradiation (typically with wavelengths below about 380 nm). When exposed to visible light, component (2) initiates polymerization with component (1) to form a pH sensitive network. Subsequent degradation of the network can later be initiated via the activation of component (3) by UV irradiation. The combination of the components (1)-(3), and optionally (4), in this example enables the resin to be polymerized exclusively with visible light and subsequently degraded with UV irradiation.

The polymerization (crosslinking) procedure can be performed according to conventional techniques, according to various embodiments. For example, the polymerizing can occur at room temperature, and the irradiation with polymerizing light can be performed for a time and intensity sufficient to achieve at least a desired amount of polymerization.

The chemical photoselectivity of the polymerization and depolymerization reaction mechanisms enables the material to be polymerized into a solid product, and subsequently depolymerized on demand, with spatial accuracy during polymerization and/or depolymerization by controlling which portions of the resin and/or polymer product are illuminated by the polymerizing and/or depolymerizing light. Accordingly, in some approaches, the spatiotemporal control may be used in a variety of applications including substrate patterning, photolithography, and hybrid additive/subtractive manufacturing techniques using vat photopolymerization processes.

In one approach, the polymer product may be exposed to depolymerizing light to depolymerize the entire product.

In another approach, only predefined portions of the polymer product are exposed to the depolymerizing light for creating localized degradation of the product. Thus, particular features or sections of a polymer structure may be removed in a controlled manner, thereby changing the shape or features of the polymer product.

During and/or after an exposure to depolymerizing light, a wash may be performed to assist in removing the remnants of the degraded polymer. For example, a wash with an alcohol may be performed. In another approach where acid degradation was performed, a wash with a basic solution may be performed to terminate degradation. The product may be sprayed, immersed, etc. Typically, the degraded polymer is in liquid form, so is fairly easy to remove.

In one approach, the entire photopolymer resin is exposed to the polymerizing light to create a polymer product. Predefined portions of the polymer product may be removed, e.g., according to a predefined pattern, via exposure to the depolymerizing light for causing depolymerization of the predefined portions of the polymer product, thereby defining features of the polymer product, and thus forming a structure with defined features.

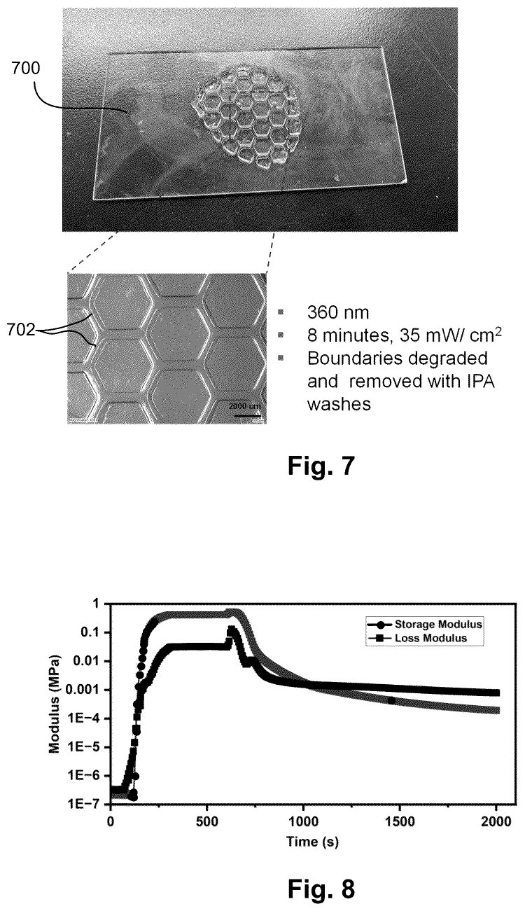

FIG. 7 depicts a polymer layer 700 formed from BMA L007 and PETMP (see FIG. 1), with triarylsulfornium hexafluoroantimonate (see FIG. 3) therein as the photoacid generator. The boundaries 702 of hexagon shaped portions were exposed to UV light at 360 nm for 8 minutes at 35 mW/cm². The boundaries disintegrated, and were removed with washes of isopropyl alcohol (IPA).

Thus, for example, a polymer mask may be formed according to a predefined pattern. A polymer layer is formed by exposing a resin as described herein to polymerizing light. A pattern is used to define which sections of the layer are removed. Such pattern may be a physical template that blocks light, a computerized pattern that controls a light beam, etc. The selected portions to be removed are exposed to depolymerizing light according to the pattern to activate the photoacid or photobase generator, thereby leaving behind a mask usable for applications such as mask-assisted patterning of a substrate existing under the mask (e.g., the mask is formed in situ on the substrate), a substrate over which the mask was placed, etc. The mask itself may later be dissolved by activating the photoacid or photobase generator within the remaining portions of the mask.

In one approach, only predefined portions of the photopolymer resin are exposed to the polymerizing light, thereby creating a polymer product with defined features (e.g., periphery, shape, members, channels of voids inside and/or extending through the structure, etc.). For example, a layer of the resin may be exposed in a checkerboard pattern, polymerizing only every other square. In a similar approach, a polymer mask may be formed according to a predefined pattern, and the pattern used to define which sections of the layer are polymerized. The unpolymerized section may be removed via washing or other conventional technique, thereby leaving behind a mask of the polymer product, which may be usable for applications such as mask-assisted patterning of a substrate existing under the mask (e.g., the mask is formed in situ on the substrate), a substrate over which the mask was placed, etc. The mask itself may later be dissolved by activating the photoacid or photobase generator within the mask.

In another example, a 3D polymer structure having a defined periphery, internal channels or voids, etc. is formed via vat polymerization of the resin by selective exposure of the photopolymer resin.

A computerized pattern which defines where exposure occurs may be used in any of the fabrication techniques mentioned herein. The computerized pattern may be created in a conventional manner, and applied by a control system to control where in the resin the exposure occurs, duration of exposure, etc. in a conventional manner.

### Experimental

U.S. Provisional Patent Application No. 63/656,502, which has been incorporated by reference, provides examples and fabrication paths that may be adapted according to the teachings herein, e.g., by addition of an effective amount of a photoacid or photobase generator, for formation of photodegradable polymeric networks according to various approaches.

The table below set forth exemplary resin formulations that worked well in terms of polymerization and depolymerization. Note, for example, that the ratio of the thiol and alkene ketal monomers relative to one another may vary above and below 1:1 with good results.

TABLE 1

| Reagent | MW | Moles | Stoic. | Mass | Wt. % |
|---|---|---|---|---|---|
| BMAL007 | 284.33 | 0.012661344 | 1.000106178 | 3.6 | 46.00051112 |
| PETMP | 488.66 | 0.006139238 | 0.484931905 | 3 | 38.33375926 |
| EtOH | 46.07 | 0.01085305 | 0.857270909 | 0.5 | 6.388959877 |
| Camphorquinone | 166.22 | 0.000360967 | 0.028512432 | 0.06 | 0.766675185 |
| Ethyl 4-(dimethylamino) | 193.24 | 0.001138481 | 0.089927381 | 0.22 | 2.811142346 |
| benzoate | | | | | |
| Pyridine | 79.1 | 7.58534E−05 | 0.005991576 | 0.006 | 0.076667519 |
| Triarylsulfonium | 818 | 0.000268949 | 0.02124397 | 0.22 | 2.811142346 |
| hexafluoroantimonate | | | | | |
| salts mixed | | | | | |
| Propylene carbonate | 102 | 0.002156863 | 0.170368305 | 0.22 | 2.811142346 |
| (PAG solution) | | | | | |
| | | | Total Mass | 7.826 | 100 |

FIG. 8 is a chart that demonstrates visible light gelation and subsequent degradation of an exemplary formulation, measured as modulus vs. time. As shown, the modulus increases during exposure to visible light during time=120 seconds(s) to about 620 s, which results from crosslinking. The modulus then decreases during exposure to UV depolymerizing light from about 640 s to 2000 s.

### In Use

Various aspects of the present invention may be performed and/or used for any suitable purpose taught or suggested herein.

This spatiotemporal control during polymerization and/or depolymerization may be useful in a variety of applications including substrate patterning, photolithography, and hybrid additive/subtractive manufacturing techniques e.g., using vat photopolymerization processes.

The materials described herein are applicable not only to 2D photolithography applications but also to 3D printing applications where complex architectures can be printed and selectively removed or degraded to form the final desired product.

Specific examples of use, according to various approaches, include photolithography, additive manufacturing, subtractive manufacturing, substrate patterning, photomasks, temporary films and 3D architectures.

The inventive concepts disclosed herein have been presented by way of example to illustrate the myriad features thereof in a plurality of illustrative scenarios, embodiments, and/or implementations. It should be appreciated that the concepts generally disclosed are to be considered as modular, and may be implemented in any combination, permutation, or synthesis thereof. In addition, any modification, alteration, or equivalent of the presently disclosed features, functions, and concepts that would be appreciated by a person having ordinary skill in the art upon reading the instant descriptions should also be considered within the scope of this disclosure.

While various embodiments have been described above, it should be understood that they have been presented by way of example only, and not limitation. Thus, the breadth and scope of an embodiment of the present invention should not be limited by any of the above-described exemplary embodiments, but should be defined only in accordance with the following claims and their equivalents.

What is claimed is:

1. A photopolymer resin capable of polymerization by exposure to polymerizing light, and characterized as enabling depolymerization of a resulting polymer product by exposure to depolymerizing light.

2. The photopolymer resin of claim 1, wherein the photopolymer resin comprises one or more pH labile monomers that include one or more polymerizable functional handles; a polymerizing light-sensitive photoinitiator; and a depolymerizing light-responsive photoacid generator or photobase generator.

3. The photopolymer resin of claim 2, wherein the one or more polymerizable functional handles of the one or more pH labile monomers are selected from the group consisting of: one or more acrylates, one or more methacrylates, one or more alkenes, one or more thiols, and one or more epoxies.

4. The photopolymer resin of claim 2, wherein at least one of the one or more pH labile monomers includes a ketal group.

5. The photopolymer resin of claim 2, wherein the photopolymer resin comprises one or more additives selected from the group consisting of a reactive diluent, an unreactive diluent, a pH stabilizer, a distribution enhancing additive, and a quencher.

6. The photopolymer resin of claim 2, further comprising an additional monomer for polymerizing with the one or more pH labile monomers.

7. The photopolymer resin of claim 6, wherein the additional monomer is a thiol.

8. The photopolymer resin of claim 2, wherein the photopolymer resin includes >0 to about 5 wt % of the photoinitiator, 0.01 to about 3 wt % of the photoacid generator or photobase generator, 0 to about 15 wt % additive(s), and the remainder monomer(s) including the one or more pH labile monomers.

9. A method, comprising forming a polymer product from the photopolymer resin of claim 1.

10. A photopolymer resin comprising:
one or more pH labile monomers that include one or more polymerizable functional handles;
>0 to about 5 wt % of a polymerizing light-sensitive photoinitiator; and
0.01 to about 3 wt % of a depolymerizing light-responsive photoacid generator or photobase generator.

11. The photopolymer resin of claim 10, wherein the one or more polymerizable functional handles of the one or more pH labile monomers are selected from the group consisting of: one or more acrylates, one or more methacrylates, one or more alkenes, one or more thiols, and one or more epoxies.

12. The photopolymer resin of claim 10, wherein at least one of the one or more pH labile monomers includes a ketal group.

13. The photopolymer resin of claim 10, wherein the photopolymer resin comprises >0 to about 15 wt % of one or more additives selected from the group consisting of a reactive diluent, an unreactive diluent, a pH stabilizer, a distribution enhancing additive, and a quencher.

14. The photopolymer resin of claim 10, further comprising an additional monomer for polymerizing with the one or more pH labile monomers.

15. The photopolymer resin of claim 14, wherein the additional monomer is a thiol.

16. A method, comprising:
exposing at least predefined portions of a photopolymer resin comprising one or more pH labile monomers and a photoinitiator to polymerizing light for causing polymerization of an exposed portion of the photopolymer resin thereby creating a polymer product, wherein the photopolymer resin further comprises a photoacid generator or photobase generator that is responsive to depolymerizing light.

17. The method of claim 16, comprising exposing at least predefined portions of the polymer product to the depolymerizing light for causing at least partial depolymerization of the polymer product.

18. The method of claim 17, wherein the polymerizing light is visible light, wherein the depolymerizing light is UV light.

19. The method of claim 16, wherein at least one of the one or more pH labile monomers includes a ketal group.

20. The method of claim 16, comprising exposing predefined portions of the polymer product to the depolymerizing light for causing depolymerization of the predefined portions of the polymer product thereby defining features of the polymer product.
